(19) United States
(12) Patent Application Publication
(10) Pub. No.: US 2004/0157168 A1
(43) Pub. Date: Aug. 12, 2004

(54) Method of improving pattern profile of thin photoresist layer

(75) Inventors: Tse-Yao Huang, Taipei (TW); Shui-Chyr Duh, Junghe City (TW); Yi-Nan Chen, Taipei (TW); Hsin-Ling Wu, Shindian City (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/413,111

(22) Filed: Apr. 14, 2003

(30) Foreign Application Priority Data
Feb. 11, 2003 (TW) 92102763

(51) Int. Cl. G03F 7/26

(52) U.S. Cl. 430/325; 430/323; 430/313

(57) ABSTRACT

A method of improving the pattern profile of a thin photoresist layer. First, a substrate is provided. Next, a thin patterned photoresist layer is formed on the substrate. An inert gas treatment is performed on the thin patterned photoresist layer. Finally, the substrate is etched using the thin patterned photoresist layer as a shield. According to the present invention, the thin patterned photoresist layer has an effective pattern profile for etching after inert gas treatment.

### BACKGROUND OF THE INVENTION

1. Field of the Invention

The present invention relates to photolithography, and in particular to a method of improving the pattern profile of a photoresist layer.

2. Description of the Related Art

Photolithography comprising priming, photoresist coating, baking, exposure, post baking, and development is used to transfer specific patterns onto semiconductor devices or integrated circuits during the fabrication process. A masking step transfers the pattern of a photomask onto a photoresist layer on the device surface by exposing the photoresist through the mask. Selected areas of the photoresist, based on the pattern of the mask, are then etched so that subsequent process steps, such as impurity introduction, oxidation, and metallization, can be performed. A semiconductor device with the desired electrical properties is then obtained after photolithography and etching. The critical factor of semiconductor device yield depends on photolithography.

As semiconductor manufacturers have sought to fabricate devices with a higher degree of circuit integration to improve device performance, it has become necessary to reduce the thickness of the photoresist layer. Otherwise, the exposure energy cannot reach the bottom of the photoresist layer, due to thick photoresist layer.

However, if the photoreisist layer is thin enough that the photoresist layer cannot provide effective shielding for etching. Thereby, undercut and footing problem usually occur accompanying the thin photoresist layer during etching. Use of a hard mask, such as polysilicon, under the thin photoresist layer is proposed, but complicates manufacture.

### SUMMARY OF THE INVENTION

Accordingly, an object of the present invention is to provide a method of improving the pattern profile of the thin photoresist layer after lithography, such that the thin photoresist layer is suitable for etching.

The key feature of the present invention is use of the inert gas treatment on the thin pattern photoresist layer before etching to harden the thin pattern photoresist layer. Thereby, the thin pattern photoresist layer provides effective shielding for etching after inert gas treatment.

To achieve these and other advantages, the invention provides a method of improving the pattern profile of the thin photoresist layer. First, a substrate comprising Si is provided. Next, a thin patterned photoresist layer is formed on the substrate. An inert gas treatment is performed on the thin patterned photoresist layer. Finally, the substrate is etched using the thin patterned photoresist layer as a shield.

The thin patterned photoresist layer formation comprises the following steps.

First, a thin photoresist layer is formed on the substrate. Next, exposure is performed on the thin photoresist layer. Development is then performed on the thin photoresist layer to form a thin patterned photoresist layer. The photoresist layer is formed by spin coating.

According to the present invention, the inert gas comprises argon (Ar). The flow of the inert gas is about 140˜150 sccm. As well, the inert gas treatment is performed at about 20˜60° C.

According to the present invention, the thickness of the thin patterned photoresist is about 3000˜3500

According to the present invention, the thin patterned photoresist layer has an effective pattern profile for etching after inert gas treatment.

### BRIEF DESCRIPTION OF THE DRAWINGS

The present invention can be more fully understood by reading the subsequent detailed description and examples with references made to the accompanying drawings, wherein:

FIGS. 1 through 6 are cross-sections showing the method according to a preferred embodiment of the present invention;

FIG. 7 is a flowchart of the method according to another preferred embodiment of the present invention;

### DETAILED DESCRIPTION OF THE INVENTION

A preferred embodiment of the present invention is now described with reference to the figures.

According to the present invention, after a thin patterned photoresist layer is treated by an inert gas, the thin patterned photoresist layer, effective for photolithography, provides a substantial performance of a shield with a suitable profile.

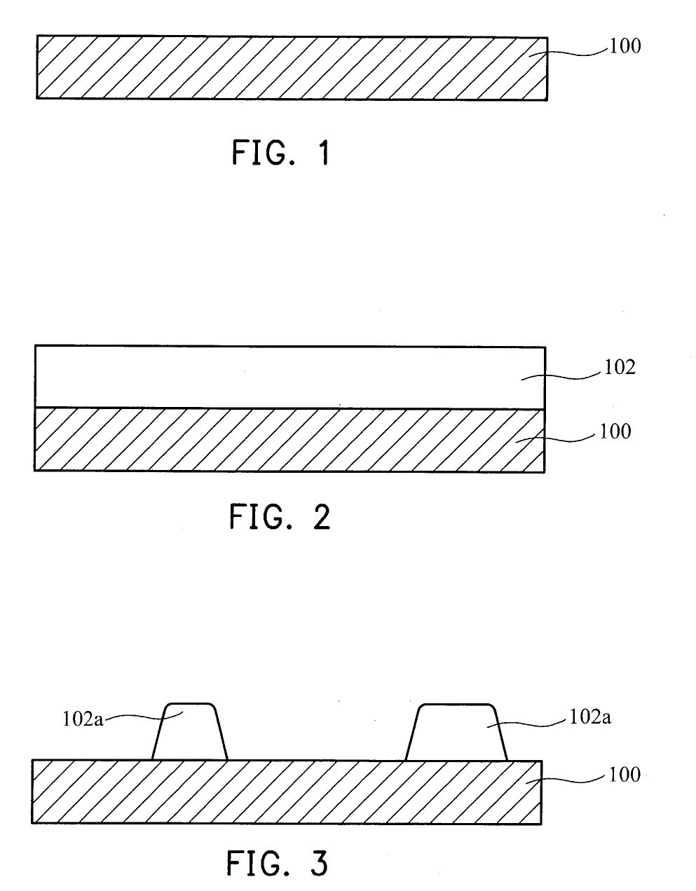

First, in step S200, a substrate 100, such as silicon, is provided, as shown in FIG. 1. The substrate 100 can comprise any semiconductor element, such as a conductive layer, an insulating layer, or a transistor therein.

Next, in step S202, a thin patterned photoresist layer 102 is preferably formed by spin coating on the substrate 100, as shown in FIG. 2. The thin photoresist layer 102, consisting of an organic material, can be a positive or negative photoresistor. According to the present invention, the thickness of the thin patterned photoresist is about 3000˜3500 Å. The photoresist layer 102 is thin enough that the following exposure energy can reach the bottom of the photoresist layer 102.

In step S204, photolithography is performed on the thin photoresist layer 102, as shown in FIG. 3. Exposure is performed by transmitting light through a mask on the thin photoresist layer 102. Development is then performed on the thin photoresist layer 102 to form a thin patterned photoresist layer 102a with an imperfect profile.

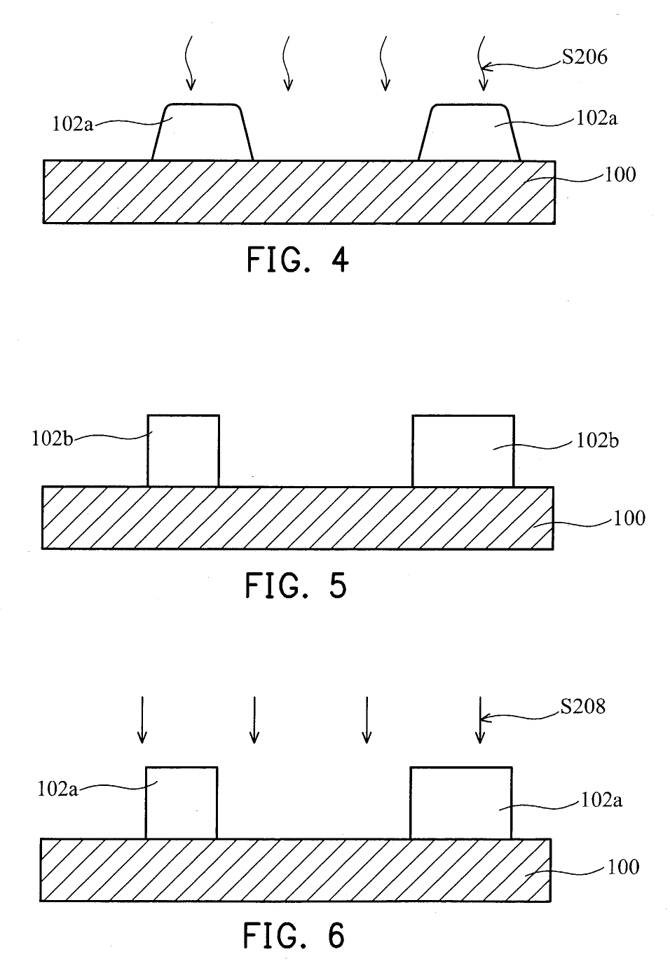

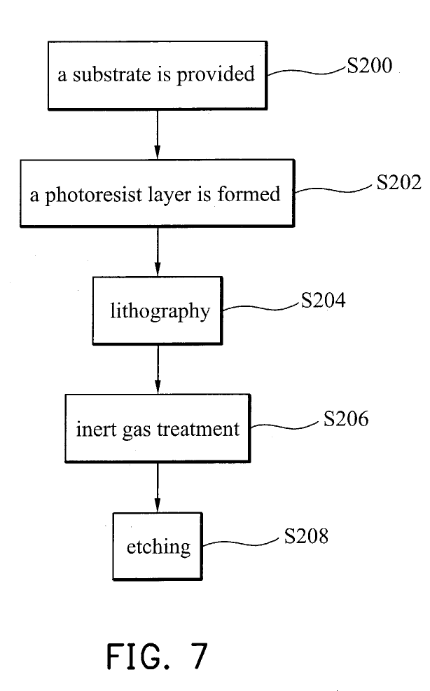

In step S206, inert gas treatment is performed on the thin patterned photoresist layer 102a, as shown in FIG. 4. The inert gas comprises Ar, He, Ne, Xe, or Rn. The flow of the inert gas is about 140˜150 sccm, with pressure of the inert gas at about 18˜86 torr at 120˜1500 W. As well, the inert gas treatment is performed at about 20˜60° C. After inert gas treatment, the thin patterned photoresist layer 102a hardens, as shown in FIG. 5.

Finally, in step S206, the substrate 100 is etched using the thin patterned photoresist layer 102a as a shield.

According to the present invention, the thin patterned photoresist layer 102a has an effective pattern profile for etching after inert gas treatment. For example, in a generation of 0.12 μm, the patterned photoresist layer of about 3400 Å can still provide effective shielding for etching after inert gas treatment. However, in order to enhance shield integrity, the thickness of the conventional photoresist layer should be more than 4100.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of improving the pattern profile of a thin photoresist layer, comprising:
providing a substrate;
forming a thin patterned photoresist layer on the substrate;
performing inert gas treatment on the thin patterned photoresist layer;
etching the substrate using the thin patterned photoresist layer as a shield.

2. The method as claimed in claim 1, wherein the substrate comprises Si.

3. The method as claimed in claim 1, wherein the step of forming a thin patterned photoresist layer further comprises:
forming a thin photoresist layer on the substrate;
performing exposure on the thin photoresist layer;
developing the thin photoresist layer to form a thin patterned photoresist layer.

4. The method as claimed in claim 3, wherein the photoresist layer is formed by spin coating.

5. The method as claimed in claim 1, wherein the inert gas comprises argon (Ar).

6. The method as claimed in claim 1, wherein the flow of the inert gas is about 140˜150 sccm.

7. The method as claimed in claim 1, wherein the thickness of the thin patterned photoresist is about 3000˜3500 Å.

8. The method as claimed in claim 1, wherein the inert gas treatment is performed at about 20˜60° C.

9. A method of improving the pattern profile of the thin photoresist layer, comprising:
providing a substrate;
forming a thin photoresist layer on the substrate;
performing exposure on the thin photoresist layer;
developing the thin photoresist layer to form a thin patterned photoresist layer;
performing inert gas treatment on the thin patterned photoresist layer;
etching the substrate using the thin patterned photoresist layer as a shield.

10. The method as claimed in claim 9, wherein the substrate comprises Si.

11. The method as claimed in claim 9, wherein the photoresist layer is formed by spin coating.

12. The method as claimed in claim 9, wherein the inert gas comprises argon (Ar).

13. The method as claimed in claim 9, wherein the flow of the inert gas is about 140˜150 sccm.

14. The method as claimed in claim 9, wherein the thickness of the thin patterned photoresist is about 3000˜3500 Å.

15. The method as claimed in claim 9, wherein the inert gas treatment is performed at about 20˜60° C.
